(19) United States
(12) Patent Application Publication
(10) Pub. No.: US 2021/0176434 A1
(43) Pub. Date: Jun. 10, 2021

(54) METHOD AND ASSEMBLY FOR DETECTING CORONA DISCHARGES OF A SYSTEM COMPRISING EQUIPMENT

(71) Applicant: Siemens Energy Global GmbH & Co. KG, Munich, Bayern (DE)

(72) Inventors: Josef Alois Birchbauer, Seiersberg (AT); Olaf Kähler, Graz (AT)

(73) Assignee: Siemens Energy Global GmbH & Co. KG, Munich, Bayern (DE)

(21) Appl. No.: 17/268,459

(22) PCT Filed: Aug. 21, 2019
(86) PCT No.: PCT/EP2019/072342

§ 371 Date: Feb. 13, 2021

(30) Foreign Application Priority Data
Aug. 22, 2018 (EP) 18190178.6

(51) Int. Cl. H04N 7/18; G01S 19/01; G01R 31/12; G01R 31/08; B64D 47/08

(52) U.S. Cl. CPC H04N 7/18; G01S 19/01; B64C 39/024; G01R 31/085; B64D 47/08; G01R 31/1218

(57) ABSTRACT

A method and a corresponding assembly for detecting corona discharges of a system of equipment includes a sensor assembly that is guided along the system by a vehicle, a first camera for detecting UV radiation is used with a daylight filter for blocking daylight for the sensor assembly, and images of the system are captured by the sensor assembly. The captured images of the camera are provided with a three-dimensional position using an analysis device. Possible corona discharges are detected in each individual image using the analysis device and are transferred into a single three-dimensional space using the respective three-dimensional position. A spatial statistic regarding the frequency of possible current discharges is generated using the analysis device, and the spatial statistic is used to detect actual corona discharges as occurring frequently and at a fixed location in contrast to random noise.

### CROSS REFERENCE TO RELATED APPLICATIONS

This application is the US National Stage of International Application No. PCT/EP2019/072342 filed 21 Aug. 2019, and claims the benefit thereof. The International Application claims the benefit of European Application No. EP18190178 filed 22 Aug. 2018. All of the applications are incorporated by reference herein in their entirety.

### FIELD OF INVENTION

The invention relates to a method and to an assembly for detecting corona discharges of a system.

### BACKGROUND OF INVENTION

The previously unpublished European patent application 17161027.2 of 03.15.2017 entitled “Verfahren and Anordnung für eine Zustandsüberwachung einer Anlage mit Betriebsmitteln” [Method and assembly for status monitoring of a system comprising equipment] discloses a method for status monitoring of a system comprising equipment, in which overview data are recorded by means of a first vehicle having an overview sensor assembly for optical recording of the system, and by means of an evaluation device, the equipment is detected in the overview data and the positions of the equipment are determined by taking the position of the first vehicle into account, characterized in that detail images of the equipment are produced by means of a second vehicle having a detail camera, which is aimed at the respective positions of the equipment. For example, only a single aircraft, for example a drone or a helicopter, is used in order, when flying over an overhead line, to detect masts and insulators by means of the overview camera, to determine the position of the insulators and subsequently to obtain high-resolution images of the insulators by means of the detail camera. In this way, damaged insulators can be detected simply and reliably.

Corona discharges at elements of an overhead line or other high-voltage infrastructures are a known and at the same time undesired physical phenomenon, which is described in detail for example on Wikipedia (permanent link: https://de.wikipedia.org/w/index.php?title=Koronaentladung&oldid=173331289). By a corona discharge, in combination with the nitrogen content of the ambient air, acidic products which attack surfaces of high-voltage fittings may be formed. Besides this, corona discharges also have other undesired side-effects such as interference with radiofrequency bands. In order to prevent corona discharges, protective fittings, so-called corona rings, are fitted on modules, such as for example insulators. Corona rings are described for example on Wikipedia (permanent link: https://de.wikipedia.org/w/index.php?title=Koronaring&oldid=171645402).

Usually, corona discharges are not visible to the human eye (especially under the effect of daylight). Cameras for the ultraviolet (UV) frequency range, for example the product DAYCOR from the company OFIL (known from the website http://www.ofilsystems.com/products) are therefore used. Such cameras are equipped with an image intensifier which can make individual light quanta visible. A daylight blocking filter is furthermore fitted in order to minimize the effect of daylight. Various preprocessing steps, with which the raw signal is converted into an image that is easier for a human observer to understand, are known in the prior art. This is for example done by superimposing an image of a system, for example a catenary for rail vehicles or an overhead line, in the visible spectrum of light with an image in the UV spectrum of light. Evaluation of whether displayed discharges represent a relevant corona is the responsibility of a human evaluating engineer.

From video recordings of overhead lines with a corona camera as described in the introduction, a certain background noise is often to be observed in the recorded signals. While numerous discharges have been recorded in one individual image, these are no longer visible in chronologically subsequent individual images. Few methods for automatically evaluating such images, particularly with a view to the position-related detection of a corona effect in a moving recording system, are known from the prior art.

The publication “An Automatic Corona-discharge Detection System for Railways Based on Solar-blind Ultraviolet Detection” by Li et al., Current Optics and Photonics, Vol 1, No. 3, June 2017, pp. 196-202 is known. In the approach described—tailored to rail vehicles—the linear movement of the detected corona points is detected directly in the image space, the concept of a so-called Hough transform (in 2D) being applied. In this case, use is made of the fact that a corona discharge in a plurality of successive images appears as a bright point moving along a straight line, if the rail vehicle is moving past on straight rail tracks. The mathematical method of the Hough transform is explained, for example, on Wikipedia (permanent link: https://de.wikipedia.org/w/index.php?title=Hough-Transformation&oldid=165672024). A further system for detecting corona discharges in the case of rail vehicles is the DayCor Rail System from the company OFILSYSTEMS, known from the website http://www.ofilsystems.com/products.

### SUMMARY OF INVENTION

An object of the invention is to provide a method with which corona discharges at systems can be established automatically and reliably.

The invention achieves this object with a method as claimed.

A system may, for example, be an electrical system such as a catenary or an overhead line. Equipment of an electrical system in the sense of the invention may, for example, be insulators or current-carrying cables.

UV light is recorded by the first camera. Light visible to humans is conventionally specified with wavelengths of between 380 nm and 780 nm, and UV radiation is typically specified at from 10 nm to 380 nm (permanent link:https://de.wikipedia.org/w/index.php?title=Elektromagnetisches_Spektrum&oldid=178702023).

Preferably, so-called soft UV radiation with a wavelength of between 230 nm and 380 nm may be detected by the first camera. Even more advantageously, soft UV radiation in the so-called solar-blind wavelength range, i.e. with a wavelength of between 240 nm and 280 nm, may be detected by the second camera.

The effect of the daylight filter of the first camera is that visible light is blocked out for this camera and corona discharges appear, for example, as bright light points or light sources in front of an otherwise substantially black background. The daylight filter is thus a daylight-blocking filter which blocks all other daylight wavelengths. The unblocked bright light points are initially registered in the scope of the invention as possible corona discharges. A wavelength range of 240-280 nm should advantageously be registered with the second camera, since in this range the UV radiation of the sun (part of the “daylight”) is filtered out by the ozone layer of the Earth. Everything which is measured in this wavelength range (assuming a functioning ozone layer) has therefore in some way originated on Earth. It may therefore be assumed that corresponding signals are man-made. Since only very few photons can be received in the restricted wavelength range, however, an image intensifier may for example be provided together with the daylight filter.

For example, a conventional computer device with a corresponding data memory may be used as the evaluation device. From the individual images of the two cameras, all registered possible corona discharges are projected into the three-dimensional (3D) space. With the aid of this projection, the statistic of the detected bright points may be determined in order to distinguish actual corona discharges from random noise of the images. Actual corona discharges always recur at the same position—in relation to the three-dimensional space—in a chronological series of individual images. This makes them distinguishable from random noise signals, which may occur only for a short time (in a small number of individual images or even only a single image) and possibly occur at random positions in a series of images. Depending on the camera system used for the sensor assembly, a suitable threshold value for a frequency of detected bright points may be established beforehand by calibration measurements or tests with artificially generated corona discharges, so that an actual corona discharge may be assumed above the threshold value for the frequency. Volatile discharge phenomena may thus be distinguished automatically from genuine discharges. In this case, in particular, the frequency of false alarms or false-positively detected discharges is greatly reduced since recurring discharge effects can be separated from spontaneous discharge effects.

It is a crucial advantage of the method according to the invention that a relationship to a three-dimensional geometry is established for the automatic detection of corona discharges. In this way, for example when flying over with an aircraft, the exact position may be detected and stored for each corona discharge. This allows accurate evaluation and optionally correctly localized maintenance or repair of detected damage. This approach allows the use of aircraft, since in the case of a mobile airborne platform, for example a helicopter or a drone, it is not possible to use the solution of Li et al. known from the prior art because the movement of the aircraft itself generally does not follow a predetermined or pre-restricted (linear) shape in the individual images (in contrast to rail vehicles).

In comparison with evaluations with stationary cameras, the invention allows the use of a freely moved camera. This allows localization of the discharges in the three-dimensional space, while for example with stationary cameras and without further prior knowledge relating to the scene being recorded, only restriction to 3D points along the visual line of the respective camera is possible.

In one embodiment of the method according to the invention, a position determination device is additionally used for the sensor device. With the position determination device, the three-dimensional position of the respective possible corona discharge or of the bright point in the UV image may be determined. For example, GPS signals may be evaluated. For example, each individual image is assigned a timestamp and an exact position of the vehicle, from which an exact position of possible corona discharges may later be calculated in the three-dimensional space with the aid of the viewing direction or the visual line of the sensor assembly. For example, a position sensor may be used to determine the viewing direction. Preferably, a position sensor which determines the alignment with the aid of the so-called inertial measurement unit (IMU) and/or an inertial navigation system (INS) can be used. Such position sensors are known, for example, from the website of the company Vectornav (https://www.vectornay.com/support/library/imu-and-ins).

In the scope of the present invention, the three-dimensional position of a possible or actual corona discharge thus already refers to a calculation result which is obtained from the position of the vehicle and the viewing angle of the camera. The sensor assembly consequently makes it possible, optionally in combination with the evaluation device, to determine the position and alignment of the UV camera accurately.

In one embodiment of the method according to the invention, a second camera for registering visible light is additionally used for the sensor assembly, images of the system being recorded with the camera and labeled with a three-dimensional position. This has the advantage that a human observer sees images (for example the images represented in FIG. 1) and may optionally carry out a manual verification or a plausibility check in relation to detected corona discharges. The second camera usually takes daylight images, with which the bright light points may be set in a spatial relation or superimposed.

In one refinement of the aforementioned embodiment, photogrammetry may be carried out with the aid of the images of the second camera by means of the evaluation device. In this case, a plurality of images of the same section of the system may be obtained by movement of the second camera along the system. As an alternative or in addition, further cameras for visible light may also be used in order to be able to obtain a plurality of images of the system at any time. With photogrammetry, from the images of the system it is possible to deduce its spatial position and/or three-dimensional shape. The principle of photogrammetry is known, for example, from Wikipedia (permanent link: https://de.wikipedia.org/w/index.php?title=Photogrammetrie&oldid=179451745).

In one embodiment of the method according to the invention, verification of the status and/or repairing of equipment at the positions of which actual corona discharges are detected is carried out. This is an advantage because an optimal operating state of the system may be restored rapidly and reliably, which prevents further damage by corona discharges, further radio interference and or even failures of the system.

In a further embodiment of the method according to the invention, information relating to equipment at the positions of possible and/or actual corona discharges is provided by means of a geoinformation system. This is an advantage because information relating to the operating state and possibly known wear or maintenance requirements is often available to the operator of the system. This information may, for example, be linked with the statistic in order to detect corona discharges even more reliably.

In a further embodiment of the method according to the invention, the spatial statistic is formed by assigning a number of entries in a quantized three-dimensional counter state array to each possible corona discharge in the three-dimensional space, visual lines in the three-dimensional space being established with the aid of a viewing direction of the sensor assembly, a frequency being entered in the counter state array in the case of intersection of a plurality of visual lines from a plurality of time-offset individual images of the sensor assembly at the same three-dimensional position. This concept uses, for example, a so-called Hough space, i.e. an extension in relation to a 3D space of the Hough approach described in the introduction. This embodiment is advantageous because it is reliable. In this case, the quantized three-dimensional counter state array is to be understood, for example, as a subdivision of the three-dimensional space into many cubes of equal size. If the position of a corona discharge lies in a particular cube, the counter for this cube is increased by 1. The person skilled in the art may find a suitable size of the cubes by means of a calibration measurement, so that the supposed corona discharges occur sufficiently frequently in a particular cube. The quantized three-dimensional counter state array is consequently used in the manner of a histogram.

In a further embodiment of the method according to the invention, the spatial statistic is formed by detecting respectively possible corona discharges in the images and projecting them into chronologically subsequent images, an increased probability of an actual corona discharge being assumed in the event of a match with a possible corona discharge detected in the subsequent images. If there are further possible corona discharges which cannot be associated with already known bright light points, further possible corona discharges are registered along the corresponding visual lines. In comparison with the preceding embodiment with a counter state array, a reduction of the memory requirement in the evaluation device is to be expected, which is advantageous.

In a further embodiment of the method according to the invention, the spatial statistic is compiled while taking into account a previously known three-dimensional model of the system, so that a search space for corona discharges in the three-dimensional model is restricted to the close proximity of the system. For example, only possible corona discharges which are located in the vicinity of the system, for example an overhead line, are registered in the three-dimensional space. Although the corona discharges do not occur directly on physical objects which are measured with conventional methods (lines, insulators etc.), they are nevertheless to be expected in the vicinity (for example at a distance of a few cm to m) of such objects. The respective back-projections along the visual lines may therefore be correlated with corresponding 3D objects. Instead of the entire visual line, the further processing may be reduced to a region around these objects. This is an advantage because the calculation outlay for the evaluation device is greatly reduced. In this embodiment, the evaluation device can find a result more rapidly for a given computing speed, or may be used with significantly reduced computing power and therefore costs.

In a further embodiment of the method according to the invention, an aircraft is used as the vehicle. An aircraft in the sense of the invention is any object which travels not only two-dimensionally on the Earth's surface, for example on a road or a rail track, but also at a height above the Earth's surface. The use of an aircraft is a great advantage because systems can be inspected rapidly and reliably by flying over, even when there are no roads or the like for inspection on the ground. This is advantageous particularly for overhead line inspection.

In a further embodiment of the method according to the invention, an airplane, a helicopter or a drone is used as the aircraft.

In a further embodiment of the method according to the invention, the evaluation device is provided in the vehicle. This is an advantage because evaluation of the image data of the sensor assembly may already be carried out during the flight. If actual corona discharges are detected, the coordinates (for example GPS data) may be sent to the operator of the system either after the end of the inspection of the system or even immediately by means of radio data communication.

In a further embodiment of the method according to the invention, the evaluation device is provided as a central server. This is an advantage because it is possible to save on weight and space for an evaluation device on-board the vehicle, which saves costs. This is an advantage in particular for aircraft. The image data registered by the two cameras may, for example, be compressed and stored in a data memory. Readout of the data memory takes place after the end of the inspection. As an alternative, the image data may be transmitted immediately by means of radio data communication to the central server. The central server may, for example, be configured as a “cloud application”.

In a further embodiment of the method according to the invention, the three-dimensional position is respectively determined with the aid of Global Positioning System (GPS) data. This is advantageous because GPS is well established, reliable and accurate.

It is furthermore an object of the invention to provide an assembly with which corona discharges at systems can be established automatically and reliably.

The invention achieves this object with an assembly as claimed. Preferred embodiments may be found in dependent claims.

In a further embodiment of the assembly according to the invention, the evaluation device is provided in the vehicle.

In a further embodiment of the assembly according to the invention, the evaluation device is provided as a central server.

The same advantages as explained in the introduction for the method according to the invention are correspondingly obtained for the assembly according to the invention and its embodiments. It is in this case clear to the person skilled in the art that the individual embodiments described for the method according to the invention, in particular the configurations of the image analysis steps carried out by means of the evaluation device, are also implemented and freely combinable in the assembly according to the invention.

### BRIEF DESCRIPTION OF THE DRAWINGS

For better explanation of the invention, in a schematic representation,

FIG. 1 shows a first superposition of an individual image in the visible light spectrum with an individual image in the UV spectrum, and

FIG. 2 shows a second superposition, occurring chronologically after the first superposition according to FIG. 1, of an individual image in the visible light spectrum with an individual image in the UV spectrum, and

FIG. 3 shows an exemplary embodiment of the invention.

### DETAILED DESCRIPTION OF INVENTION

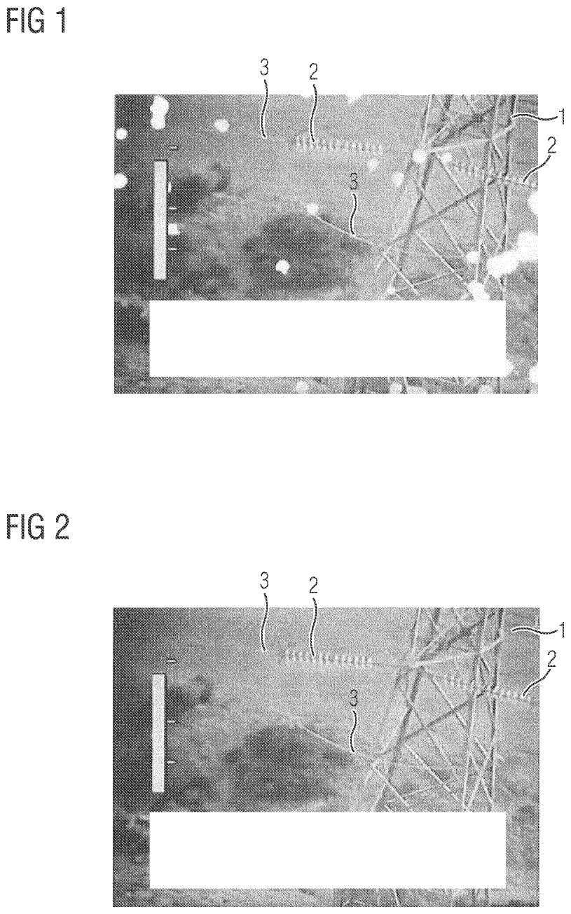

FIGS. 1 and 2 show known published images. A mast 1 with cables 3 and equipment, for example insulators 2, is shown. Numerous white or bright points, which are registered as UV sources by means of the UV camera and are superimposed on the visible image, may be seen clearly. These bright points are possibly corona discharges. The same mast 1 is shown somewhat later in FIG. 2, no bright points being visible any longer.

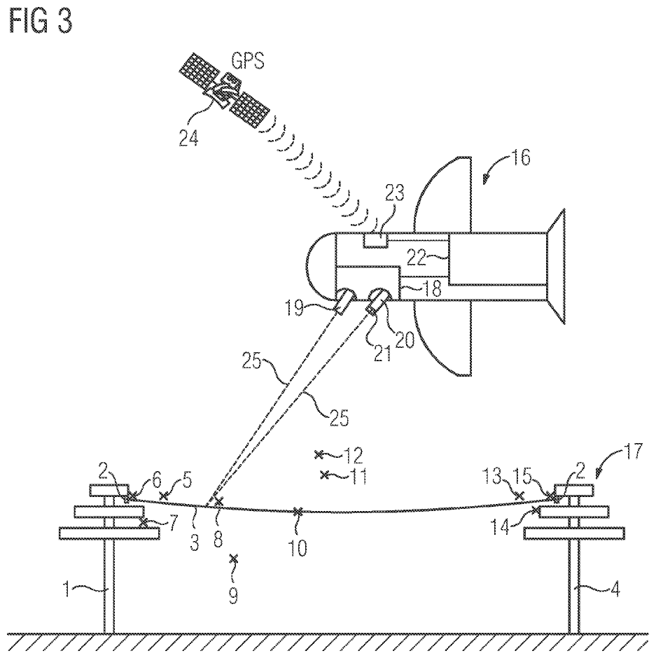

FIG. 3 shows an exemplary embodiment of the invention. A system 17, an overhead line having a first mast 1 and a second mast 4, insulators 2 and cables 3 are represented. There are cables 3 on the masts 1, 4. A drone 16 which moves a sensor assembly 18 along the system is used as the vehicle. The sensor assembly 18 comprises a second camera 19 for registering visible light and a first camera 20 for registering UV radiation. The first camera 20 additionally comprises a daylight filter 21 for blocking out daylight. Images of the system 17 are recorded with the sensor assembly 18 and processed on-board the drone 16 with an evaluation device 22. The images of the two cameras 19, 20 are labeled with a three-dimensional position which is established by means of a GPS satellite and a position determination device 23. With the position determination device 23, a timestamp and an exact position of the drone 16 is assigned to each individual image, from which the exact position of possible corona discharges 5-15 may later be calculated in the three-dimensional space with the aid of the viewing direction or the visual line 25 of the sensor assembly 18.

The evaluation device 22 detects possible corona discharges 5-15 in each individual image of the second camera 20 as bright points. With the aid of the respective three-dimensional position of the bright point, the latter is transferred into a single three-dimensional space. This makes it possible to analyze the information from a sequence of images. The evaluation device may compile a spatial statistic relating to the frequency of the possible corona discharges. With the aid of the spatial statistic, actual corona discharges 5-8, 10, 13-15 may be detected as stationary and occurring more frequently in comparison with noise. In the example shown, the corona discharges 5-8, 10, 13-15 which lie in the immediate vicinity of the system 17 have thereby been identified. That is to say, the actual corona discharges are imaged more frequently in a sequence of images than random noise, which repeatedly occurs at other positions while not being identifiable at a single position for a long time over several individual images.

A geoinformation system (not represented) may provide information relating to equipment 2, 3 and the positions of possible 5-15 and/or actual 5-8, 10, 13-15 corona discharges.

1. A method for detecting corona discharges of a system comprising equipment, the method comprising:
moving a sensor assembly by means of a vehicle along the system comprising equipment,
using a first camera for registering UV radiation with a daylight filter for blocking out daylight for the sensor assembly,
recording images of the system by means of the sensor assembly,
labeling, by means of an evaluation device, the images of the camera with a three-dimensional position,
detecting and transferring, by means of the evaluation device, possible corona discharges in each individual image into a single three-dimensional space with the aid of the respective three-dimensional position, and
compiling, by means of the evaluation device, a spatial statistic relating to the frequency of possible corona discharges, with the aid of which actual corona discharges are detected as stationary and occurring more frequently in comparison with noise.

2. The method as claimed in claim 1, further comprising:
additionally using a second camera for registering visible light for the sensor assembly, with images of the system being recorded with the camera and labeled with a three-dimensional position.

3. The method as claimed in claim 1, further comprising:
verifying the status and/or repairing of equipment at the positions of which actual corona discharges are detected.

4. The method as claimed in claim 1,
wherein information relating to equipment at the positions of possible and/or actual corona discharges is provided by means of a geoinformation system.

5. The method as claimed in claim 1,
wherein the spatial statistic is formed by assigning a number of entries in a quantized three-dimensional counter state array to each possible corona discharge in the three-dimensional space, visual lines in the three-dimensional space being established with the aid of a viewing direction of the sensor assembly, a frequency being entered in the counter state array in the case of intersection of a plurality of visual lines from a plurality of time-offset individual images of the sensor assembly at the same three-dimensional position.

6. The method as claimed in claim 1,
wherein the spatial statistic is formed by detecting respectively possible corona discharges in the images and projecting them into chronologically subsequent images, an increased probability of an actual corona discharge being assumed in the event of a match with a possible corona discharge detected in the subsequent images.

7. The method as claimed in claim 1,
wherein the spatial statistic is compiled while taking into account a previously known three-dimensional model of the system, so that a search space for corona discharges in the three-dimensional space is restricted to the close proximity of the system.

8. The method as claimed in claim 1,
wherein an aircraft is used as the vehicle.

9. The method as claimed in claim 8,
wherein an airplane, a helicopter or a drone is used as the aircraft.

10. The method as claimed in claim 1,
wherein the evaluation device is provided in the vehicle.

11. The method as claimed in claim 1,
wherein the evaluation device is provided as a central server.

12. The method as claimed in claim 1,
wherein the three-dimensional position is respectively determined with the aid of Global Positioning System data.

13. An assembly for detecting corona discharges of a system comprising equipment, the assembly comprising:
a vehicle which is configured to move a sensor assembly along a system comprising equipment,
the sensor assembly comprising a first camera for registering UV radiation, and the first camera comprising a daylight filter for blocking out daylight, and
the sensor assembly being configured to record images of the system, and
the vehicle comprising a position determination device,
an evaluation device which is configured to label the images of the camera with a three-dimensional position, and to detect possible corona discharges in each individual image and transfer them into a single three-dimensional space with the aid of the respective three-dimensional position, and to compile a spatial statistic relating to the frequency of the possible corona discharges, with the aid of which actual corona discharges are detectable as stationary and occurring more frequently in comparison with noise.

14. The assembly as claimed in claim 13,
wherein the sensor assembly comprises a second camera for registering visible light, images of the system, recorded by means of the camera, being labelable with a three-dimensional position by means of the position determination device.

15. The assembly as claimed in claim 13,
wherein the vehicle is an airplane, a helicopter or a drone.
